(19) United States
(12) Patent Application Publication
(10) Pub. No.: US 2026/0371889 A1
(43) Pub. Date: Nov. 19, 2026

(54) DISPLAY DEVICE AND ELECTRONIC DEVICE INCLUDING THE SAME

(71) Applicant: Samsung Display Co., Ltd., Yongin-si (KR)

(72) Inventors: Yongjin JEE, Yongin-si (KR); Hwanhee JEONG, Yongin-si (KR)

(73) Assignee: Samsung Display Co., Ltd., Yongin-si (KR)

(21) Appl. No.: 19/440,144

(22) Filed: Jan. 5, 2026

(30) Foreign Application Priority Data
May 16, 2025 (KR) 10-2025-0063946

(51) Int. Cl. H10K 59/40; H10K 59/131; H10K 59/80; H10K 59/88

(52) U.S. Cl. CPC H10K 59/40; H10K 59/131; H10K 59/87; H10K 59/88

(57) ABSTRACT

A display device may include: a first-first touch electrode and a second-first touch electrode, arranged in a first direction with respect to each other; a first-second touch electrode and a second-second touch electrode, arranged in a second direction intersecting the first direction with respect to each other; and a first connection line connecting the first-first touch electrode to the second-first touch electrode, wherein the first-first touch electrode and the second-first touch electrode are each connected to the first connection line through a respective first contact hole, and at least one from among the first-first touch electrode, the second-first touch electrode, the first-second touch electrode, and the second-second touch electrode includes a dummy contact portions that is in direct contact with an upper surface of the second insulating layer through a dummy contact hole.

### CROSS-REFERENCE TO RELATED APPLICATION

This application is based on and claims priority under 35 U.S.C. §119 to Korean Patent Application No. 10-2025-0063946, filed on May 16, 2025, in the Korean Intellectual Property Office, the disclosure of which is incorporated by reference herein in its entirety.

### BACKGROUND

### Field

Some embodiments of the present disclosure relate to a display device and an electronic device including the same.

### Description of Related Art

Recently, as electronic devices including a display device are widely used in portable forms, technologies for applying touch functions to display devices have been adopted. For example, in addition to a display function, a display device can also function as an input device by recognizing the position of a user′s finger or pen in contact with a surface of the display device.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

However, when an electronic device is used outside, external light may be incident on a display device, and the external light may be reflected by various structures included in the display device. In this process, when the external light is reflected differently in a specific area than in other areas, the display quality may not be good because the external light reflected in the specific area is highlighted and perceived.

According to some embodiments of the present disclosure, a display device with excellent display quality and an electronic device including the same may be provided. However, such an aspect is a non-limiting example, and the scope of the present disclosure is not limited thereby.

Additional aspects will be set forth in part in the description which follows and, in part, will be apparent from the description, or may be learned by practice of the presented example embodiments of the present disclosure.

According to some embodiments of the present disclosure, a display device may include: a substrate; a display layer on the substrate and including a plurality of pixels; an encapsulation layer on the display layer; a first insulating layer on the encapsulation layer; a second insulating layer on the first insulating layer; a third insulating layer on the second insulating layer; a first-first touch electrode on the third insulating layer; a second-first touch electrode on the third insulating layer, the second-first touch electrode being in a first direction from the first-first touch electrode; a first-second touch electrode on the third insulating layer; a second-second touch electrode on the third insulating layer, the second-second touch electrode being in a second direction, intersecting the first direction, from the first-second touch electrode; and a first connection line between the first insulating layer and the second insulating layer, and connecting the first-first touch electrode and the second-first touch electrode, wherein the first-first touch electrode is connected to the first connection line through a first-first contact hole of the second insulating layer and a first-second contact hole of the third insulating layer, the first-second contact hole overlapping with the first-first contact hole, wherein the second-first touch electrode is connected to the first connection line through a second-first contact hole of the second insulating layer and a second-second contact hole of the third insulating layer, the second-second contact hole overlapping with the second-first contact hole, and wherein at least one from among the first-first touch electrode, the second-first touch electrode, the first-second touch electrode, and the second-second touch electrode includes a dummy contact portion that is in direct contact with an upper surface of the second insulating layer through a dummy contact hole of the third insulating layer.

According to some embodiments of the present disclosure, each of the first-first touch electrode, the second-first touch electrode, the first-second touch electrode, and the second-second touch electrode includes a mesh structure including a plurality of wires, the plurality of wires intersecting with each other in a plan view of the display device.

According to some embodiments of the present disclosure, the dummy contact hole overlaps with at least one of intersection areas in which the plurality of wires intersect with each other in the plan view.

According to some embodiments of the present disclosure, the first-first contact hole, the first-second contact hole, the second-first contact hole, and the second-second contact hole overlap with at least one of intersection areas in which the plurality of wires intersect with each other in the plan view.

According to some embodiments of the present disclosure, the dummy contact hole is in one intersection area from among the intersection areas, the one intersection area not overlapping with the first-first contact hole, the first-second contact hole, the second-first contact hole, and the second-second contact hole.

According to some embodiments of the present disclosure, a width of a portion of the first-first contact hole adjacent to an upper surface of the first connection line is greater than a width of a portion of the first-second contact hole adjacent to the upper surface of the first connection line.

According to some embodiments of the present disclosure, the second insulating layer includes an inorganic insulating material, and the third insulating layer includes an organic insulating material.

According to some embodiments of the present disclosure, the dummy contact portion overlaps with the first connection line, wherein at least one from among the first-first touch electrode, the second-first touch electrode, the first-second touch electrode, and the second-second touch electrode includes an additional dummy contact portion that is direct contact with the upper surface of the second insulating layer through an additional dummy contact hole of the third insulating layer, and wherein the additional dummy contact portion does not overlap with the first connection line.

According to some embodiments of the present disclosure, each of the first-first touch electrode, the second-first touch electrode, the first-second touch electrode, and the second-second touch electrode includes a metal.

According to some embodiments of the present disclosure, the display device further includes a second connection line that connects the first-second touch electrode and the second-second touch electrode, and wherein the second connection line is in a same layer as a layer of the first-second touch electrode and the second-second touch electrode.

According to some embodiments of the present disclosure, an electronic device may include: a substrate; a display layer on the substrate and including a plurality of pixels; an encapsulation layer on the display layer; a first insulating layer on the encapsulation layer; a second insulating layer on the first insulating layer; a third insulating layer on the second insulating layer; a first-first touch electrode on the third insulating layer; a second-first touch electrode on the third insulating layer, the second-first touch electrode being in a first direction from the first-first touch electrode; a first-second touch electrode on the third insulating layer; a second-second touch electrode on the third insulating layer, the second-second touch electrode being in a second direction, intersecting the first direction, from the first-second touch electrode; and a first connection line between the first insulating layer and the second insulating layer, and connecting the first-first touch electrode and the second-first touch electrode, wherein each of the first-first touch electrode, the second-first touch electrode, the first-second touch electrode, and the second-second touch electrode includes a mesh structure including a plurality of wires, the plurality of wires intersecting with each other in a plan view, wherein the first-first touch electrode is connected to the first connection line through a first-first contact hole of the second insulating layer and a first-second contact hole of the third insulating layer, the first-second contact hole overlapping with the first-first contact hole, wherein the second-first touch electrode is connected to the first connection line through a second-first contact hole of the second insulating layer and a second-second contact hole of the third insulating layer, the second-second contact hole overlapping with the second-first contact hole, and wherein at least one from among the first-first touch electrode, the second-first touch electrode, the first-second touch electrode, and the second-second touch electrode includes a dummy contact portion that is in direct contact with an upper surface of the second insulating layer through a dummy contact hole of the third insulating layer.

According to some embodiments of the present disclosure, the dummy contact hole overlaps with at least one of intersection areas in which the plurality of wires intersect with each other in the plan view.

According to some embodiments of the present disclosure, the first-first contact hole and the first-second contact hole overlap with at least one of intersection areas in which the plurality of wires intersect with each other in the plan view.

According to some embodiments of the present disclosure, the dummy contact hole is in one intersection area from among the intersection areas, the one intersection area not overlapping with the first-first contact hole, the second-first contact hole, the second-first contact hole, and the second-second contact hole.

According to some embodiments of the present disclosure, a width of a portion of the first-first contact hole adjacent to an upper surface of the first connection line is greater than a width of a portion of the first-second contact hole adjacent to the upper surface of the first connection line.

According to some embodiments of the present disclosure, the second insulating layer includes an inorganic insulating material, and the third insulating layer includes an organic insulating material.

According to some embodiments of the present disclosure, the dummy contact portion overlaps with the first connection line, wherein at least one from among the first-first touch electrode, the second-first touch electrode, the first-second touch electrode, and the second-second touch electrode includes an additional dummy contact portion that is in direct contact with the upper surface of the second insulating layer through an additional dummy contact hole of the third insulating layer, and wherein the additional dummy contact portion does not overlap with the first connection line.

According to some embodiments of the present disclosure, each of the first-first touch electrode, the second-first touch electrode, the first-second touch electrode, and the second-second touch electrode includes a metal.

According to some embodiments of the present disclosure, the electronic device further includes a second connection line that connects the first-second touch electrode and the second-second touch electrode, and wherein the second connection line is in a same layer as a layer of the first-second touch electrode and the second-second touch electrode.

According to some embodiments of the present disclosure, the electronic device further includes a sensing line connected to the first-first touch electrode, the second-first touch electrode, the first-second touch electrode, or the second-second touch electrode, and configured to transmit an electrical signal generated from the first-first touch electrode, the second-first touch electrode, the first-second touch electrode, or the second-second touch electrode.

According to some embodiments of the present disclosure, a touch electrode layer may include: a first insulating layer; a second insulating layer on the first insulating layer; a third insulating layer on the second insulating layer; a first-first touch electrode on the third insulating layer; a second-first touch electrode on the third insulating layer, the second-first touch electrode being in a first direction from the first-first touch electrode; a first-second touch electrode on the third insulating layer; a second-second touch electrode on the third insulating layer, the second-second touch electrode being in a second direction, intersecting the first direction, from the first-second touch electrode; and a first connection line between the first insulating layer and the second insulating layer, and connecting the first-first touch electrode and the second-first touch electrode, wherein the first-first touch electrode is connected to the first connection line through a first contact hole of the second insulating layer and a second contact hole of the third insulating layer, the second contact hole overlapping with the first contact hole, and wherein at least one from among the first-first touch electrode, the second-first touch electrode, the first-second touch electrode, and the second-second touch electrode comprises a dummy contact portion that is in direct contact with an upper surface of the second insulating layer through a dummy contact hole of the third insulating layer.

Other aspects, features, and advantages of embodiments of the present disclosure than those described above will become apparent from the following drawings, claims, and detailed description of the present disclosure.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a schematic block diagram of an electronic device according to an embodiment;

FIG. 2 is a set of schematic diagrams of electronic devices according to various embodiments;

FIG. 3 is a schematic plan view of a display device according to an embodiment;

FIG. 4 is a cross-sectional view of the display device taken along a line I-I’ of FIG. 3;

FIG. 5 is a schematic plan view of a touch electrode layer according to an embodiment;

FIG. 6 is an enlarged view of a region A of FIG. 5;

FIG. 7A is an enlarged view of an area of a touch electrode layer according to an embodiment;

FIG. 7B is an enlarged view of an area of a touch electrode layer according to an embodiment;

FIG. 8 is a cross-sectional view of the touch electrode layer taken along a line II-II’ of FIG. 6;

FIG. 9 is a cross-sectional view of the touch electrode layer taken along a line III-III’ of FIG. 6;

FIG. 10 is a plan view of a touch electrode layer according to an embodiment;

FIG. 11 is a cross-sectional view of the touch electrode layer taken along a line IV-IV’ of FIG. 10; and

FIG. 12 is a cross-sectional view of a contact portion and a dummy contact portion, according to an embodiment.

### DETAILED DESCRIPTION

Reference will now be made in detail to non-limiting example embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects of the present disclosure. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Various modifications may be applied to embodiments of the present disclosure, and particular non-limiting example embodiments will be illustrated in the drawings and described below. Effects and aspects of embodiments of the present disclosure,, including methods, will be clearer referring to the below description along with the accompanying drawings. However, embodiments of the present disclosure may be implemented in various forms, and are not limited to the example embodiments presented below.

In the description with reference to the drawings, the same or corresponding elements are indicated by the same reference numerals and redundant descriptions thereof may be omitted.

In the specification, it will be understood that although the terms “first,” “second,” etc. may be used to describe various elements, these elements should not be limited by these terms. These elements are only used to distinguish one element from another.

In the specification, as used herein, the singular forms “a,” “an,” and “the” are intended to include the plural forms as well, unless the context clearly indicates otherwise.

In the specification, it will be further understood that the terms “comprises” (or “includes”) and/or “comprising” (or “including”) used herein specify the presence of stated features or elements, but do not preclude the presence or addition of one or more other features or components.

In the specification, it will be understood that when an element, such as a layer, a film, a region, or a plate, is referred to as being “on” another element, the element can be directly on the other element or intervening elements may be present thereon.

In the specification, it will be understood that when a layer, region, or element is referred to as being “connected to” another layer, region, or element, it can be directly connected to the other layer, region, or component or indirectly connected to the other layer, region, or component via intervening layers, regions, or components. For example, in the specification, when a layer, region, or component is referred to as being electrically connected to another layer, region, or component, it can be directly electrically connected to the other layer, region, or component or indirectly electrically connected to the other layer, region, or component via intervening layers, regions, or components.

In the specification, the x-axis, the y-axis, and the z-axis are not limited to three axes of a rectangular coordinate system, and may be interpreted in a broader sense. For example, the x-axis, the y-axis, and the z-axis may be perpendicular to one another, or may represent different directions that are not perpendicular to one another.

In the specification, the term “about” or “approximately” used to refer to any numerical value may mean including values within a range generally accepted in the art, due to measurement limitations or errors, etc. For example, “about” may mean including values in a range of ±30%, ±20%, ±10%, or ±5% of a certain value.

In the specification, a configuration B being placed directly on a configuration A may mean that no separate adhesive layer or adhesive member is placed between the configuration A and the configuration B. Here, the configuration B may be formed on a base surface provided by the configuration A after the configuration A is formed.

In the specification, A overlapping B may indicate that, when looking at a plane (e.g., an x-y plane) perpendicular to one direction (e.g., a z-axis direction) from the one direction, at least a part of A and at least a part of B are arranged to overlap on the plane (e.g., may overlap in the one direction).

In the specification, when a certain embodiment may be implemented differently, a specific process order may be performed differently from the described order. For example, two consecutively described processes may be performed substantially at the same time or performed in an order opposite to the described order.

Sizes of elements in the drawings may be exaggerated for convenience of explanation. For example, since sizes and thicknesses of elements in the drawings may be arbitrarily illustrated for convenience of explanation, embodiments of the present disclosure are not limited thereto.

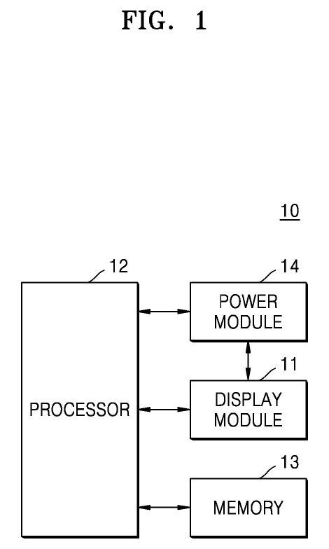

FIG. 1 is a schematic block diagram of an electronic device 10 according to an embodiment. Referring to FIG. 1, the electronic device 10 according to an embodiment may include a display module 11, at least one processor 12, a memory 13, and a power module 14.

The display module 11 may include a display device according to an embodiment to be described below. The display module 11 may include auxiliary components to operate the display device. For example, the display module 11 may include the display device and a driving circuit or a flexible printed circuit board (FPCB) which is electrically connected to the display device.

The at least one processor 12 may include at least one from among a central processing unit (CPU), an application processor (AP), a graphics processing unit (GPU), a communication processor (CP), an image signal processor (ISP), and a controller.

The memory 13 may store data information for the operation of the at least one processor 12 or the display module 11. When the at least one processor 12 executes an application stored in the memory 13, an image data signal and/or an input control signal may be transmitted to the display module 11, and the display module 11 may process the received signal and output image information through a display screen.

The power module 14 may include a power supply module (e.g., a power supply), such as a power adaptor or a battery device, and a power conversion module (e.g., a power converter) that converts power supplied by the power supply module to generate power for the operation of the electronic device 10.

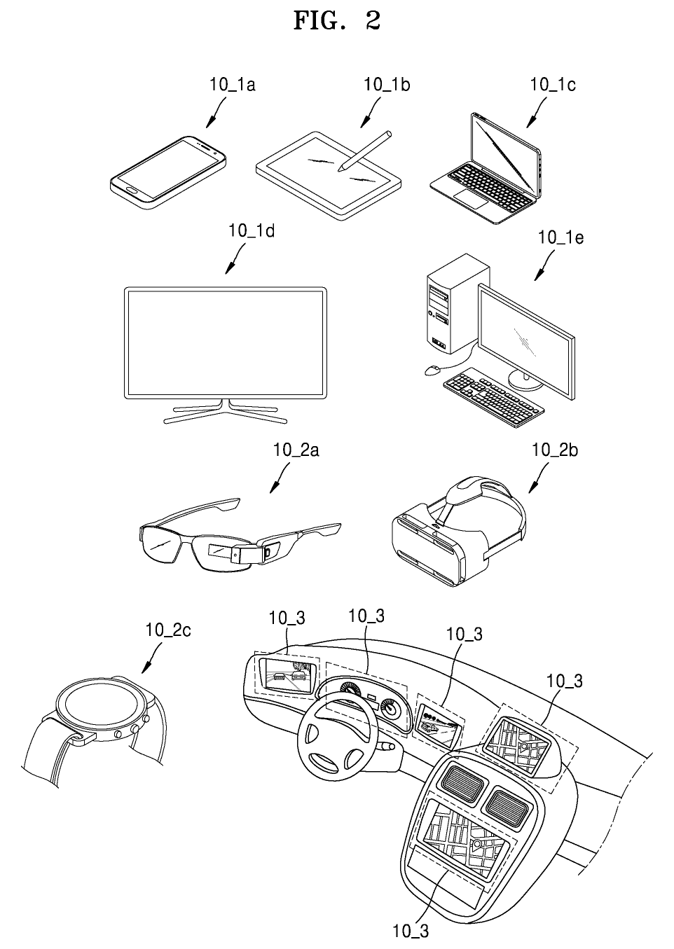

FIG. 2 is a set of schematic diagrams of electronic devices according to various embodiments.

Referring to FIG. 2, various electronic devices, to which display devices according to embodiments of the present disclosure may be applied, may include not only electronic devices for image display (e.g., a smartphone 10_1a, a tablet PC 10_1b, a laptop 10_1c, a TV 10_1d, or a desktop monitor 10_1e) but also wearable electronic devices including a display module (e.g., smart glasses 10_2a, a head mount display 10_2b, or a smart watch 10_2c), and electronic devices 10_3 for vehicles including a display module (e.g., an instrument panel, a center fascia, a center information display (CID) arranged on a dashboard, or a room mirror display of vehicles).

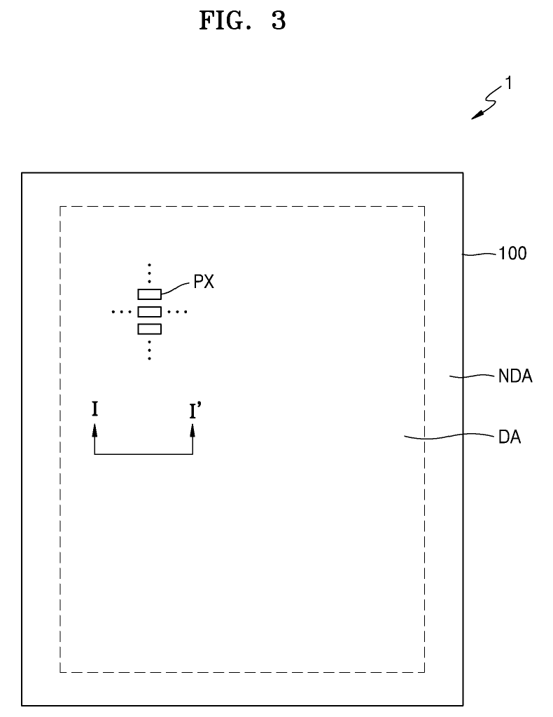

FIG. 3 is a schematic plan view of a display device 1 according to an embodiment.

Referring to FIG. 3, the display device 1 may include a display area DA that implements an image and a non-display area NDA that does not implement an image. The display device 1 may provide an image through an array of a plurality of sub-pixels PX that are two-dimensionally arranged on an x-y plane in the display area DA. The sub-pixels PX may emit light of different colors from each other, and may include, for example, a red sub-pixel, a green sub-pixel, and a blue sub-pixel.

In an embodiment, the plurality of sub-pixels PX may include a first sub-pixel, a second sub-pixel, and a third sub-pixel, and in the following description, for convenience of explanation, a case in which the first sub-pixel is a red sub-pixel, the second sub-pixel is a green sub-pixel, and the third sub-pixel is a blue sub-pixel is described.

In an embodiment, the first sub-pixel, the second sub-pixel, and the third sub-pixel may emit red light, green light, and blue light, respectively, and the display device 1 may provide an image by using the light emitted from the sub-pixels PX.

In the disclosure, the “red” or “red light” may refer to light corresponding to a wavelength band of about 630 nm to about 780 nm, the “green” or “green light” may refer to light corresponding to a wavelength band of about 495 nm to about 570 nm, and the “blue” or “blue light” may refer to light corresponding to a wavelength band of about 450 nm to about 495 nm.

The non-display area NDA is an area that does not provide an image, and may entirely surround the display area DA. A driver or a main voltage line to provide electrical signals or power to sub-pixel circuits may be arranged in the non-display area NDA. The non-display area NDA may include a pad that is an area to which an electronic device or a printed circuit board may be electrically connected.

The display area DA may have a polygonal shape including a quadrangle, as illustrated in FIG. 3. For example, the display area DA may have a rectangular shape in which its horizontal length is greater than its vertical length, a rectangular shape in which its horizontal length is less than its vertical length, or a square shape. In another embodiment, the display area DA may be circular, oval, triangular, or polygonal such as pentagonal. Furthermore, although the display device 1 of FIG. 3 is illustrated as a flat type display device, the display device 1 may be implemented in various shapes, such as a flexible display device, a foldable display device, or a rollable display device.

In an embodiment, the display device 1 may be an organic light-emitting display device. In another embodiment, the display device 1 may be an inorganic light-emitting display device or a quantum dot light-emitting display device. For example, an emission layer of a display element included in the display device may include an organic material, an inorganic material, quantum dots, both an organic material and quantum dots, both an inorganic material and quantum dots, or all of an organic material, an inorganic material, and quantum dots.

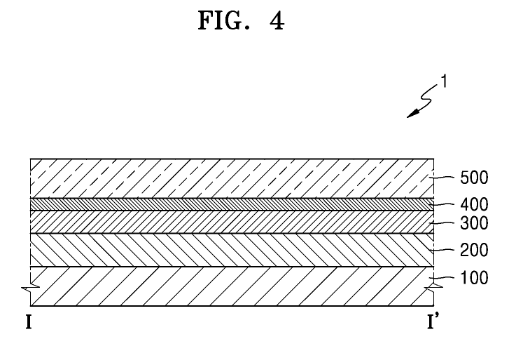

FIG. 4 is a cross-sectional view of the display device taken along a line I-I′ of FIG. 3.

Referring to FIG. 4, the display device 1 may include a substrate 100, and a display layer 200 that forms the display area DA on the substrate 100.

The substrate 100 may include various materials, such as a glass material, a metal material, or a plastic material (e.g., polyethylen terephthalate (PET), polyethylen naphthalate (PEN), or polyimide (PI)).

The display layer 200 may be disposed on the substrate 100, may include a plurality of sub-pixels, and may provide a certain image.

An encapsulation layer 300 may be disposed on the display layer 200. For example, the encapsulation layer 300 may be disposed to face the substrate 100 with the display layer 200 between the encapsulation layer 300 and the substrate 100, and may protect the display layer 200 from external moisture or oxygen.

A touch electrode layer 400 may be disposed on the encapsulation layer 300. The touch electrode layer 400 may include a plurality of touch electrodes having conductivity (e.g., electrical conductivity). For example, the touch electrode layer 400 may be of a capacitive type. The touch electrode layer 400 may be used to output coordinates of a position at which an object, such as a user’s hand, approaches or contacts the surface of the touch electrode layer 400, by utilizing a change in capacitance that occurs when the object approaches or contacts the surface.

An optical functional layer 500 may be disposed on the touch electrode layer 400. The optical functional layer 500 may be, for example, a polarizing plate. In another example, the optical functional layer 500 may be a layer including a black matrix and a color filter. In another example, the optical functional layer 500 may be a window member.

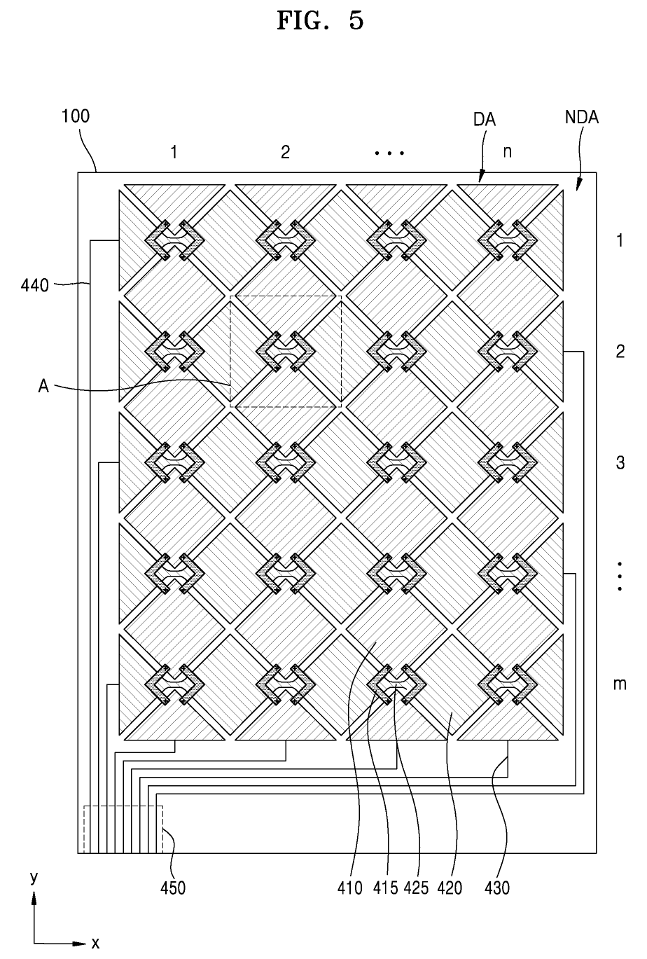

FIG. 5 is a schematic plan view of a touch electrode layer according to an embodiment.

Referring to FIG. 5, the touch electrode layer 400 according to an embodiment may include first touch electrodes 410 arranged in a first direction (e.g., the y-axis direction) with respect to each other, and second touch electrodes 420 arranged in a second direction (e.g., the x-axis direction) with respect to each other. Each of the first touch electrodes 410 and each of the second touch electrodes 420 may generate an electrical signal when an object such as a user’ hand approaches or contacts, and transmits the electrical signal to a pad 450 through a first sensing line 430 and a second sensing line 440.

The second touch electrodes 420 and the first touch electrodes 410 may be arranged in rows and columns. For example, a first column may be formed in the first direction (e.g., the y-axis direction), a second column may be formed in the first direction (e.g., the y-axis direction) adjacent to the first column, and by repeating the above process, an n-th column (n is a natural number) extending in the first direction (e.g., the y-axis direction) may be finally formed. Furthermore, a first row may be formed in the second direction (e.g., the x-axis direction), a second row may be formed in the second direction (e.g., the x-axis direction) adjacent to the first row, and by repeating the process, an m-th row (m is a natural number) extending in the second direction (e.g., the x-axis direction) may be finally formed.

The first touch electrodes 410 may be arranged in the first column to the n-th column, and the second touch electrodes 420 may be arranged in the first row to the m-th row.

The first touch electrodes 410 arranged in a same column (e.g., the n-th column) in the first direction (e.g., the y-axis direction) may be electrically connected to each other, and the second touch electrodes 420 arranged in a same row (e.g., the m-th row) in the second direction (e.g., the x-axis direction) may be electrically connected to each other.

The first touch electrodes 410 arranged in the same column (e.g., the n-th column, where n is a natural number) in the first direction (e.g., the y-axis direction) may be electrically connected to each other by at least one first connection line 415. The second touch electrodes 420 arranged in the same row (e.g., the m-th row, where m is a natural number) in the second direction (e.g., the x-axis direction) may be electrically connected to each other by at least one second connection line 425. In the present disclosure, it is illustrated that the second touch electrodes 420 are electrically connected to each other by one second connection line 425 and the first touch electrodes 410 are electrically connected to each other by two first connection lines 415. However, embodiment of the present disclosure are not limited thereto.

The second touch electrodes 420 arranged in the same row (e.g., the m-th row) in the second direction (e.g., the x-axis direction) may be connected to each other by the second connection lines 425, and the second touch electrodes 420 and the second connection line 425 may be integrally formed. As described below, the first touch electrodes 410 and the second touch electrodes 420 may be formed in the same layer. However, as the electrical signals generated by the first touch electrodes 410 and the electrical signals generated by the second touch electrode 420 may be required to be distinguished from each other, the first touch electrode 410 and the second touch electrode 420 may not be electrically connected to each other. Accordingly, when the second touch electrodes 420 and the second connection line 425 are integrally formed in the same layer, the first touch electrodes 410 may be spaced apart from each other in the same column (e.g., the n-th column) in the first direction (e.g., the y-axis direction). The first touch electrodes 410 may be electrically connected to each other by the first connection line 415 formed in a different layer from the first touch electrodes 410.

As illustrated in FIG. 5, the first touch electrodes 410 arranged in the same column (e.g., n-th column, where n is a natural number) in the first direction (e.g., the y-axis direction) may be electrically connected to the first sensing line 430. For example, the first touch electrodes 410 arranged in the first column, the first touch electrodes 410 arranged in the second column, …, and the first touch electrodes 410 arranged in the same column (e.g., n-th column) may be electrically connected to different first sensing lines 430, respectively. This may be similar for the second touch electrodes 420. In other words, the second touch electrodes 420 arranged in the same row (e.g., the m-th row, where m is a natural number) in the second direction (e.g., the x-axis direction) may be electrically connected to the second sensing lines 440. For example, the second touch electrodes 420 arranged in the first row, the second touch electrodes 420 arranged in the second row, …, and the second touch electrodes 420 arranged in the m-th row may be electrically connected to different second sensing lines 440, respectively.

The electrical signals generated from the first touch electrode 410 and the second touch electrode 420 may be transmitted to the pad 450 through the first sensing line 430 and the second sensing line 440, and to a circuit portion including a position detection circuit via the pad 450.

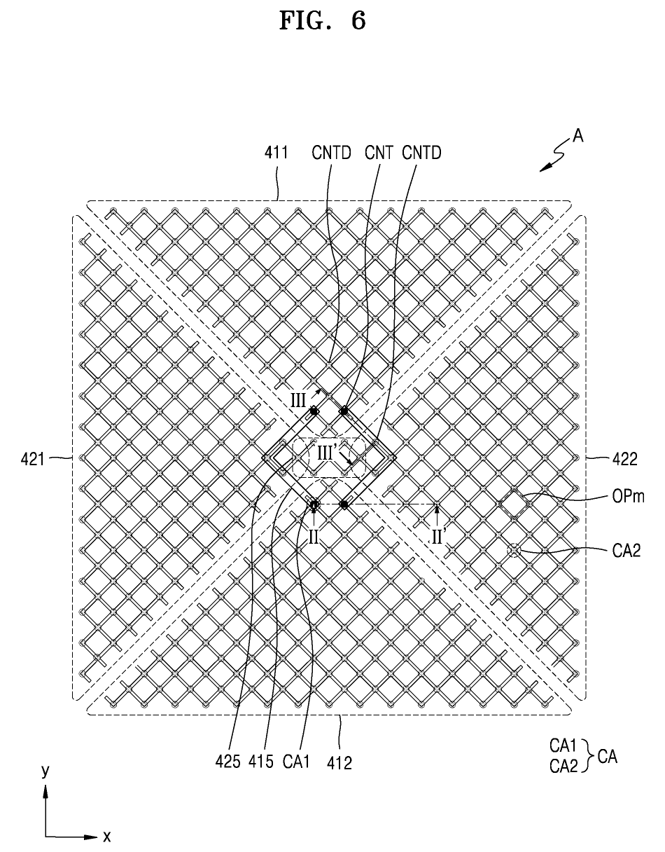

FIG. 6 is an enlarged view of a region A of FIG. 5. FIG. 6 illustrates parts of the first touch electrodes 410, parts of the second touch electrodes 420, the first connection line 415, and the second connection line 425.

Referring to FIG. 6, a first-first touch electrode 411 and a second-first touch electrode 412 may be spaced apart from each other in the first direction (e.g., the y-axis direction). A first-second touch electrode 421 and a second-second touch electrode 422 may be spaced apart from each other in the second direction (e.g., the x-axis direction).

The first-first touch electrode 411, the second-first touch electrode 412, the first-second touch electrode 421, and the second-second touch electrode 422 may each have a mesh (or a grid or a lattice) structure in which a plurality of wires intersect with each other in a plan view.

The plurality of wires may include a conductive material to transmit an electrical signal that occurs when an object, such as a user’s hand, approaches or touches a touch electrode. In an embodiment, the wires may include metal. In an embodiment, the wires may include aluminum (Al). The first connection line 415 and the second connection line 425 may each also include a conductive material to transmit an electrical signal. In an embodiment, the first connection line 415 and the second connection line 425 may each include metal, and in an embodiment, the first connection line 415 and the second connection line 425 may each include Al.

The first-first touch electrode 411, the second-first touch electrode 412, the first-second touch electrode 421, and the second-second touch electrode 422 may have the same or similar shape as each other.

As described above, the touch electrodes may each have a mesh (or a grid or a lattice) structure in which in which a plurality of wires intersect with each other in a plan view. In an embodiment, the touch electrodes may each have a net or mesh structure in which wires extending in one direction (e.g., a +x, +y direction) and wires extending in another direction (e.g., the +x, -y direction) intersecting with the one direction. As such, as each touch electrode has a mesh structure, an opening OPm may be defined by two wires extending in one direction and adjacent to each other and other two wires extending in another direction and adjacent to each other.

As the display layer 200 may include the sub-pixels PX in FIG. 3 and the touch electrode layer 400 may be positioned above the display layer 200, in order to prevent the light emitted from the sub-pixels PX in FIG. 3 from being blocked by the wires, the wires may not overlap with the sub-pixels PX in FIG. 3. In other words, the opening OPm described above may overlap with the sub-pixels PX in FIG. 3 in a plan view. In other words, the touch electrode may be formed such that, in a plan view, the boundaries of the openings OPms in the mesh structure surround at least part of the sub-pixel PX in FIG. 3. In an embodiment, the openings OPms may each overlap with one from among the first sub-pixel, the second sub-pixel, and the third sub-pixel.

The first-first touch electrode 411, the second-first touch electrode 412, the first-second touch electrode 421, and the second-second touch electrode 422 may each have a mesh structure, and the first touch electrodes (e.g., the first-first touch electrode 411 and the second-first touch electrode 412) and the second touch electrodes (e.g., the first-second touch electrode 421 and the second-second touch electrode 422) are electrically insulated from each other. For example, the mesh structure is discontinued at the boundaries of the first touch electrodes (e.g., the first-first touch electrode 411 and the second-first touch electrode 412) and the second touch electrodes (e.g., the first-second touch electrode 421 and the second-second touch electrode 422).

In an embodiment, the first touch electrodes (e.g., the first-first touch electrode 411 and the second-first touch electrode 412) and the second touch electrodes (e.g., the first-second touch electrode 421 and the second-second touch electrode 422) may be arranged such that a corner of the first-first touch electrode 411 and a corner of the second-first touch electrode 412 are adjacent to each other, a corner of the first-second touch electrode 421 and a corner of the second-second touch electrode 422 are adjacent to each other, a first side of the first-first touch electrode 411 and a first side of the first-second touch electrode 421 are adjacent to each other, a second side of the first-first touch electrode 411 and a first side of the second-second touch electrode 422 are adjacent to each other, a first side of the second-first touch electrode 412 and a second side of the first-second touch electrode 421 are adjacent to each other, and a second side of the second-first touch electrode 412 and a second side of the second-second touch electrode 422 are adjacent to each other.

The first-second touch electrode 421 and the second-second touch electrode 422 may be connected to each other by the second connection line 425. In an embodiment, the first-second touch electrode 421 and the second-second touch electrode 422 may be integrally formed with the second connection line 425. In an embodiment, the second connection line 425 may also have the same mesh structure as the mesh structures of the first-second touch electrode 421 and the second-second touch electrode 422.

Although spaced apart from each other, the first-first touch electrode 411 and the second-first touch electrode 412 may be electrically connected to each other by one or more first connection lines 415.

The shape of the first connection line 415 in a plan view may be a shape that is arranged along a mesh structure formed by the wires forming the touch electrodes. In other words, in a plan view, the first connection line 415 may include a part extending in one direction (e.g., a +x, +y direction) in which the wires extend and another part extending in another direction (e.g., the +x, -y direction) intersecting with the one direction. Like the wires, the first connection line 415 configured as above may not overlap with the sub-pixels PX in FIG. 3. Although FIG. 6 illustrates that the first connection line 415 has an “L” shape that is bent once in a plan view, embodiments of the present disclosure are not limited thereto. The first connection line 415 may have any shape that does not overlap with the sub-pixels PX in FIG. 3 and that is capable of electrically connecting the first-first touch electrode 411 to the second-first touch electrode 412. In an embodiment, the first connection line 415 may have a shape that is bent twice in a plan view. In an embodiment, the first connection line 415 may have a mesh structure that overlaps with the wires of the touch electrodes.

The first connection line 415 may be in contact with the first-first touch electrode 411 and the second-first touch electrode 412 at contact portions CNT of the first-first touch electrode 411 and the second-first touch electrode 412.

When the mesh structure described above is viewed in a plan view, an area where a plurality of wires intersect with each other may be referred to as an intersection area CA. In an embodiment, the contact portion CNT may overlap with one of the intersection areas CAs in which a plurality of wires intersect with each other in a plan view. As the first-first touch electrode 411 and the second-first touch electrode 412 may be electrically connected to each other by the first connection line 415, the first-first touch electrode 411 and the second-first touch electrode 412 may each include an intersection area CA1 in which the contact portion CNT is disposed. However, the first-second touch electrode 421 and the second-second touch electrode 422 may not include the intersection area CA1 in which the contact portion CNT is disposed. Although FIG. 6 illustrates that each of the first-first touch electrode 411 and the second-first touch electrode 412 includes two contact portions CNT, embodiments of the disclosure are not limited thereto. In an embodiment, each of the first-first touch electrode 411 and the second-first touch electrode 412 may include one contact portion CNT or three or more contact portions CNT.

The touch electrodes may include dummy contact portions CNTDs, and in an embodiment, the dummy contact portion CNTD may overlap with one of the intersection areas CAs. As the dummy contact portion CNTD and the contact portion CNT may not be concurrently formed in the same intersection area CA, the dummy contact portion CNTD may be disposed in an intersection area CA2 among the intersection areas CAs, in which the contact portion CNT is not disposed. In this state, the contact portion CNT or the dummy contact portion CNTD being “disposed” in the intersection area CA may have the same meaning as the contact portion CNT or the dummy contact portion CNTD overlapping with the intersection area CA.

In the embodiment illustrated in FIG. 6, the dummy contact portion CNTD may be disposed in all intersection areas CA2s in which the contact portion CNT is not disposed.

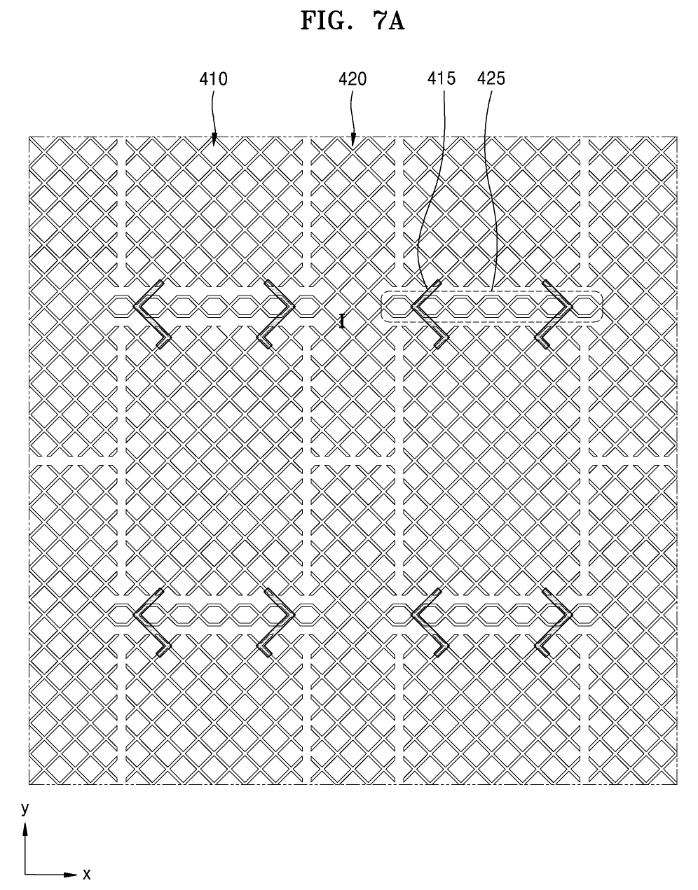

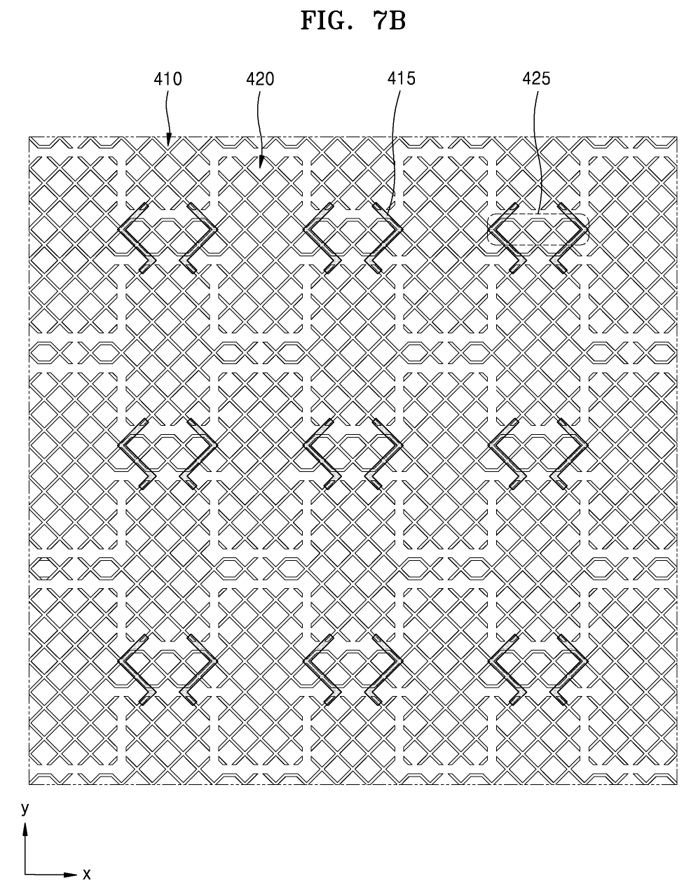

FIGS. 5 and 6 illustrate that each of the first-first touch electrode 411, the second-first touch electrode 412, the first-second touch electrode 421, and the second-second touch electrode 422, which have a mesh structure, has a shape of a quadrangle (e.g., a rhombus). However, embodiments of the present disclosure are not limited thereto. FIGS. 7A and 7B are enlarged views of an area of a touch electrode layer according to another embodiment.

Referring to FIG. 7A and 7B, the first touch electrodes 410 may have a rectangular shape, and the first touch electrodes 410, which are spaced apart from each other in the first direction (e.g., the y-axis direction), may be electrically connected to each other by two first connection lines 415. The second touch electrodes 420 may have a rectangular shape, and the second touch electrodes 420, which are spaced apart from each other in the second direction (e.g., the x-axis direction), may be connected by the second connection line 425 that is integrally formed with the second touch electrodes 420. FIG. 7A illustrates that the first touch electrode 410 and the second touch electrode 420 have different sizes from each other, and FIG. 7B illustrates that the first touch electrode 410 and the second touch electrode 420 have the same size as each other. As such, as long as the touch electrodes that are arranged in the first direction and electrically connected to each other, and the touch electrodes that are arranged in the second direction and are electrically connected to each other, are capable of covering a plane, any shape and arrangement of the touch electrodes may be possible.

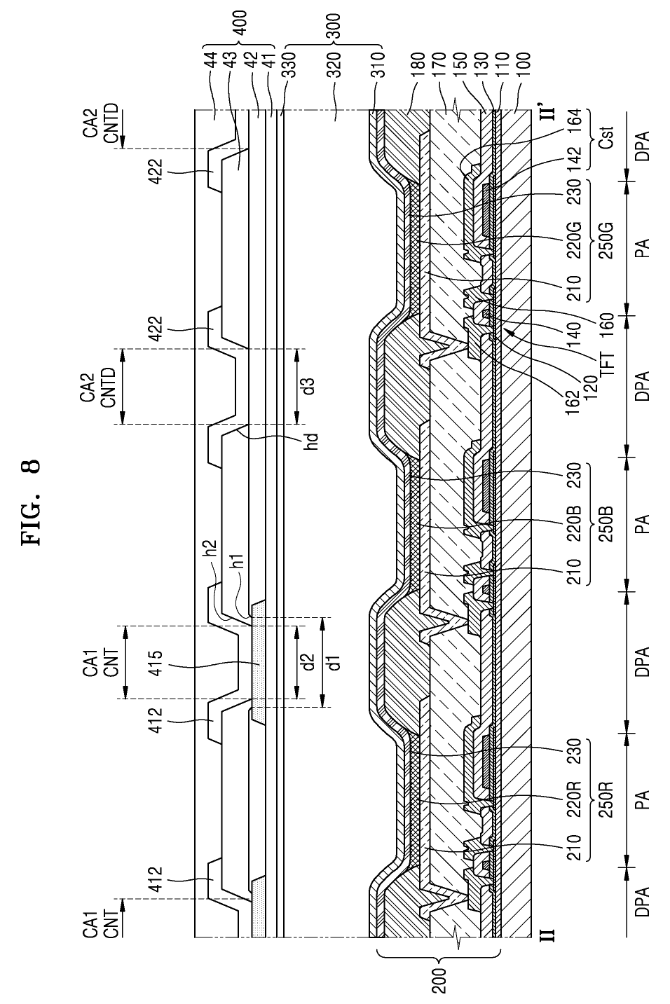

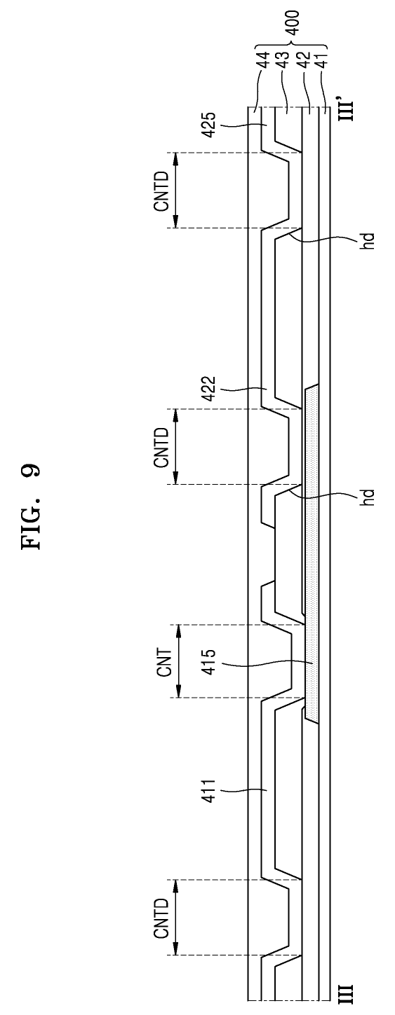

FIG. 8 is a cross-sectional view of the touch electrode layer taken along a line II-II′ of FIG. 6, and FIG. 9 is a cross-sectional view of the touch electrode layer taken along line III-III′ of FIG. 6. FIG. 9 illustrates only the touch electrode layer 400 on a cross-sectional view.

Referring to FIG. 8, the display layer 200 may be disposed on the substrate 100, and the display layer 200 may include organic light-emitting elements (e.g., a red organic light-emitting element 250R, a blue organic light-emitting element 250B, and a green organic light-emitting element 250G), and each of the organic light-emitting elements (e.g., the red organic light-emitting element 250R, the blue organic light-emitting element 250B, and the green organic light-emitting element 250G) may be electrically connected to a thin film transistor TFT and a storage capacitor Cst.

The thin film transistor TFT may include a semiconductor layer 120 and a gate electrode 140 overlapping with a partial area (channel region) of the semiconductor layer 120, and a source electrode 160 and a drain electrode 162 which may be connected to the semiconductor layer 120. The semiconductor layer 120 may include an inorganic semiconductor such as silicon, an organic semiconductor, or an oxide semiconductor material. The semiconductor layer 120 may include a source region, a drain region, and a channel region therebetween. The gate electrode 140 may include one or more materials from among Al, platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu), and may be formed in a single layer or multilayer.

A buffer layer 110 for preventing infiltration of impurities may be provided between the semiconductor layer 120 and the substrate 100, a gate insulating layer 130 may be provided between the semiconductor layer 120 and the gate electrode 140, and an interlayer insulating layer may be disposed on the gate electrode 140. The buffer layer 110 may include an inorganic material, such as silicon oxide (SiOx), silicon nitride (SiNx), silicon oxynitride (SiON), aluminum oxide (Al₂O₃), aluminum nitride (AlN), titanium oxide (TiO₂), or titanium nitride (TiN). The gate insulating layer 130 may include a material such as SiNx or SiOx, and the interlayer insulating layer may be formed in a single layer or multilayer including a material such as SiNx, SiOx, or SiON.

The source electrode 160 and the drain electrode 162 may be located on the interlayer insulating layer 150, and may be connected to the source region and the drain region of the semiconductor layer 120, respectively. According to an embodiment, the source region and the drain region of the semiconductor layer 120 may be understood as a source electrode and a drain electrode, respectively. The source electrode 160 and the drain electrode 162 may each include one or more materials from among Al, Pt, Pd, Ag, Mg, Au, Ni, Nd, Ir, Cr, Li, Ca, Mo, Ti, W, and Cu, and may be formed in a single layer or multilayer.

The storage capacitor Cst may include a lower electrode 142 and an upper electrode 164. The lower electrode 142 may include the same material as a material of the gate electrode 140 described above, and the upper electrode 164 may include the same material as a material of the source electrode 160 or the drain electrode 162, but embodiments of the present disclosure are not limited thereto.

The thin film transistor TFT and the storage capacitor Cst may be covered by a planarization insulating layer 170. The planarization insulating layer 170 may include SiO₂, SiNx, SiON, Al₂O₃, TiO₂, Ta₂O₅, HfO₂, ZrO₂, BST, or PZT. Alternatively, the planarization insulating layer 170 may include an organic insulating material such as, for example, a general purpose polymer such as polymethylmethacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof. Alternatively, the planarization insulating layer 170 may include both of the inorganic insulating material and the organic insulating material described above.

The organic light-emitting elements (e.g., the red organic light-emitting element 250R, the blue organic light-emitting element 250B, and the green organic light-emitting element 250G) may be disposed on the planarization insulating layer 170. Each of the organic light-emitting elements (e.g., the red organic light-emitting element 250R, the blue organic light-emitting element 250B, and the green organic light-emitting element 250G) may be electrically connected to the thin film transistor TFT through a contact hole defined by the planarization insulating layer 170. The organic light-emitting elements (e.g., the red organic light-emitting element 250R, the blue organic light-emitting element 250B, and the green organic light-emitting element 250G) may emit red light, blue light, and green light, respectively.

The red organic light-emitting element 250R may include a pixel electrode 210, a red organic emission layer 220R that emits red light, and a counter electrode 230, the blue organic light-emitting element 250B may include a pixel electrode 210, a blue organic emission layer 220B that emits blue light, and a counter electrode 230, and the green organic light-emitting element 250G may include a pixel electrode 210, a green organic emission layer 220G that emits green light, and a counter electrode 230.

A plurality of pixels electrode 210 may be arranged to correspond to each pixel area PA, and may be a reflective electrode. The pixel electrode 210 may be formed by forming a reflective film including Ag, Mg, Al, Pt, Pd, Au, Ni, Nd, Ir, Cr, or compounds thereof, and further forming a film of indium tin oxide (ITO), indium zinc oxide (IZO), zinc oxide (ZnO), indium oxide (In₂O₃) on the reflective film. For example, the pixel electrode 210 may be a triple layer of ITO/Ag/ITO.

A pixel defining layer 180 may have openings that expose the central portion of the pixel electrodes 210. Furthermore, by increasing a distance between the edge of the pixel electrode 210 and the counter electrode 230, arc may be prevented from being generated at the edge (end portion) of the pixel electrode 210. The pixel defining layer 180 may include an organic insulating material, such as PI or hexamethyldisiloxane (HMDSO).

The red organic emission layer 220R may include a fluorescent material or a phosphorescent material that emits red light, the blue organic emission layer 220B may include a fluorescent material or a phosphorescent material that emits blue light, and the green organic emission layer 220G may include a fluorescent material or a phosphorescent material that emits green light.

The counter electrode 230 may be a (semi-)transparent electrode. The counter electrode 230 may be a layer including Ag, Mg, Al, Yb, Ca, Li, Au, or compounds thereof, or a layer including a (semi-)transparent material, such as ITO, IZO, ZnO, or In₂O₃. In an embodiment, the counter electrode 230 may include a metal thin film including Ag and Mg.

The encapsulation layer 300 may include at least one inorganic layer and at least one organic layer. For example, the encapsulation layer 300 may include a first inorganic layer 310, a second inorganic layer 330, and an organic layer 320 provided therebetween. The first inorganic layer 310 and the second inorganic layer 330 may each include SiOx, SiNx, or SiON, and the organic layer 320 may include one or more materials selected from among polyethylene terephthalate, polyethylene naphthalate, polycarbonate, PI, polyethylene sulfonate, polyoxymethylene, polyarylate, and HMDSO. In the present embodiment, a case in which the encapsulation layer 300 includes the first inorganic layer 310, the organic layer 320, and the second inorganic layer 330, which are sequentially stacked, is described, but in a state in which an inorganic layer and an organic layer are alternately stacked, the number of stacking may be changed. In the present embodiment, a case in which the encapsulation layer 300 is a thin film encapsulation film including an inorganic layer and an organic layer that are alternatively stacked is described, but in another embodiment, the encapsulation layer 300 may be a rigid, transmissive encapsulation substrate.

The touch electrode layer 400 may be disposed on the encapsulation layer 300.

The touch electrode layer 400 may include a first insulating layer 41 disposed on the encapsulation layer 300, a second insulating layer 42 disposed on the first insulating layer 41, a third insulating layer 43 disposed on the second insulating layer 42, a protective layer 44 disposed on the third insulating layer 43, the first touch electrodes 410 of FIG. 5 disposed on the third insulating layer 43 in the first direction (e.g., the y-axis direction), the second touch electrodes 420 of FIG. 5 disposed on the third insulating layer 43 in the second direction (e.g., the x-axis direction), the second connection line 425 of FIG. 5 disposed on the third insulating layer 43 and electrically connecting the second touch electrodes 420 of FIG. 5, and the first connection line 415 disposed on the first insulating layer 41 and electrically connecting the first touch electrodes 410 of FIG. 5. In this state, it can be said that the first connection line 415 is disposed between the first insulating layer 41 and the second insulating layer 42. Furthermore, it can be said that the first insulating layer 41 is disposed on the second inorganic layer 330.

The first insulating layer 41 and the second insulating layer 42 may each include an inorganic insulating material. The first insulating layer 41 and the second insulating layer 42 may each include an inorganic insulating material, such as SiO₂, SiNx, and SiON, and may have a single layer or multilayer structure including the inorganic insulating material described above.

The third insulating layer 43 may include an organic insulating material. The third insulating layer 43 may include an organic insulating material such as, for example, a general purpose polymer such as PMMA or PS, a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and blends thereof.

The protective layer 44 may include an inorganic insulating material. The protective layer 44 may include an inorganic insulating material, such as SiO₂, SiNx, and SiON, and include a single layer or multilayer structure including the inorganic insulating material described above.

Although FIG. 8 illustrates the second-first touch electrode 412, the first-first touch electrode 411 of FIG. 6 may have substantially the same structure as the structure of the second-first touch electrode 412. Referring to FIG. 8, in the intersection area CA1 in which the contact portion CNT is disposed, the second-first touch electrode 412 may be connected to the first connection line 415 through a first contact hole h1 and a second contact hole h2.

The first contact hole h1 may be defined in the second insulating layer 42. For example, the first contact hole h1 may expose a part of an upper surface of the first connection line 415 by penetrating the second insulating layer 42. The second contact hole h2 may be defined in the third insulating layer 43, and may overlap with the first contact hole h1. The second contact hole h2 may expose a part of the upper surface of the first connection line 415 by penetrating the third insulating layer 43.

As the part of the upper surface of the first connection line 415 is exposed by the first contact hole h1 and the second contact hole h2, the second-first touch electrode 412 may be in direct contact with the first connection line 415 through the first contact hole h1 and the second contact hole h2.

Referring to FIGS. 6 and 8, a contact hole may be formed even in the intersection area CA2 in which the contact portion CNT is not disposed. The dummy contact portion CNTD may be formed in a part or all of the intersection area CA2 in which the contact portion CNT is not disposed. Accordingly, the first-first touch electrode 411, the second-first touch electrode 412, the first-second touch electrode 421, and the second-second touch electrode 422 may each include a dummy contact portion CNTD. As the configurations (e.g., shapes) of the dummy contact portions CNTD of the touch electrodes may be similar to each other, in the following description, with reference to FIG. 8, the dummy contact portion CNTD of the second-second touch electrode 422 is mainly described.

The dummy contact portion CNTD of the second-second touch electrode 422 may be in direct contact with the upper surface of the second insulating layer 42 through a dummy contact hole hd. In this state, the dummy contact hole hd may be defined in the third insulating layer 43, and may expose part of the upper surface of the second insulating layer 42. Accordingly, the second-second touch electrode 422 may be in direct contact with the upper surface of the second insulating layer 42 through the dummy contact hole hd.

With reference to FIGS. 6 an d8, as the contact portion CNT may be formed in part of the intersection area CA in which wires intersect with each other, it can be said that the first contact hole h1 and the second contact hole h2 overlap with at least one of the intersection areas CA that are areas in which a plurality of wires intersect with each other. In detail, the first contact hole h1 and the second contact hole h2 may overlap with at least one of the intersection areas CA included in the first-first touch electrode 411 and the second-first touch electrode 412. As the dummy contact hole hd may not be formed concurrently with the first contact hole h1 and the second contact hole h2, the dummy contact hole hd may be disposed in the intersection area CA2 of the intersection area CA, in which the first contact hole h1 and the second contact hole h2 do not overlap with each other.

The width of a portion of the first contact hole h1 adjacent to the upper surface of the first connection line 415 may be referred to as a width d1 of the first contact hole h1, the width of a portion of the second contact hole h2 adjacent to the upper surface of the first connection line 415 may be referred to as a width d2 of the second contact hole h2, and the width of a portion of the dummy contact hole hd adjacent to the upper surface of the second insulating layer 42 may be referred to as a width d3 of the dummy contact hole hd. In this state, the width d1 of the first contact hole h1 may be greater than the width d2 of the second contact hole h2. Furthermore, the width d2 of the second contact hole h2 may be the same as or similar to the width d3 of the dummy contact hole hd. As such, the cross-sectional shapes of the second-first touch electrode 412 and the second-second touch electrode 422 in the intersection area CA may be similar to each other.

In the following description, with reference to FIG. 9, the contact portion CNT and the dummy contact portion CNTD included in the touch electrode, and the dummy contact portion CNTD included in the second connection line 425, are described. FIG. 9 illustrates only the touch electrode layer 400 in the cross-sectional view of FIG. 6, and contents already described with reference to FIGS. 6 and 8 may not be repeated.

Referring to FIGS. 6 and 9, the first-first touch electrode 411 may include a contact portion CNT and a dummy contact portion CNTD, and the second-second touch electrode 422 may include a dummy contact portion CNTD.

In this state, the dummy contact portion CNTD included in the second-second touch electrode 422 may overlap with the first connection line 415. In this case, however, in the dummy contact portion CNTD, the second-second touch electrode 422 may not be in contact with the first connection line 415. In other words, even when the dummy contact portion CNTD is formed at a position overlapping with the first connection line 415, in the dummy contact portion CNTD, the second-second touch electrode 422 may be in direct contact with the upper surface of the second insulating layer 42 through the dummy contact hole hd.

Accordingly, referring to FIGS. 6-9, the dummy contact portion CNTD included in the touch electrodes may include a first dummy contact portion that overlaps with the first connection line 415 as illustrated in FIG. 9, and a second dummy contact portion that does not overlap with the first connection line 415 as illustrated in In FIG. 8.

FIG. 9 illustrates that the second connection line 425 is integrally formed with the second-second touch electrode 422. The second connection line 425 that has a mesh structure like the touch electrode includes the intersection area CA, and thus the second connection line 425 may include a dummy contact portion CNTD. The second connection line 425 may be in direct contact with the upper surface of the second insulating layer 42 through a dummy contact hole hd. The second connection line 425, like the second-second touch electrode 422, may not include the contact portion CNT.

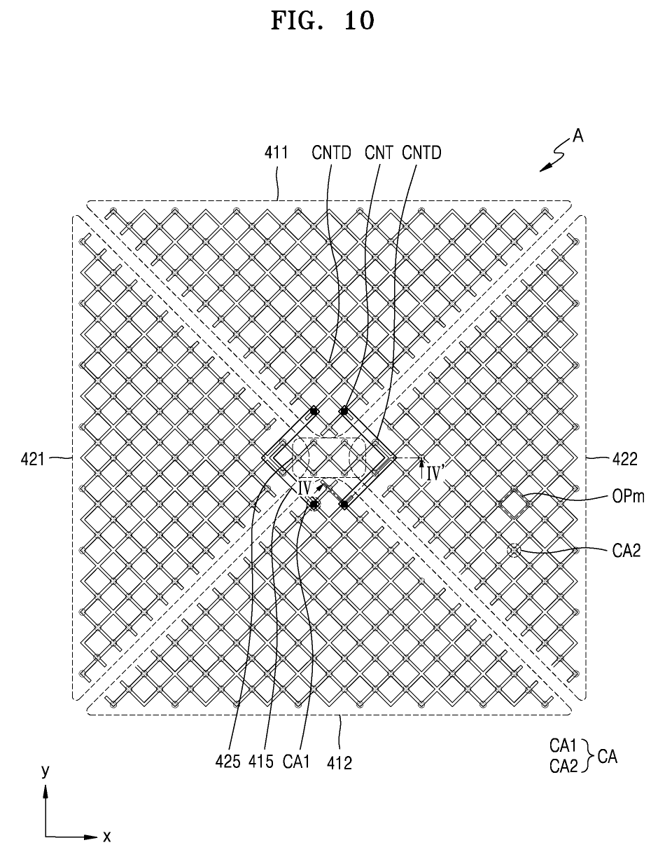

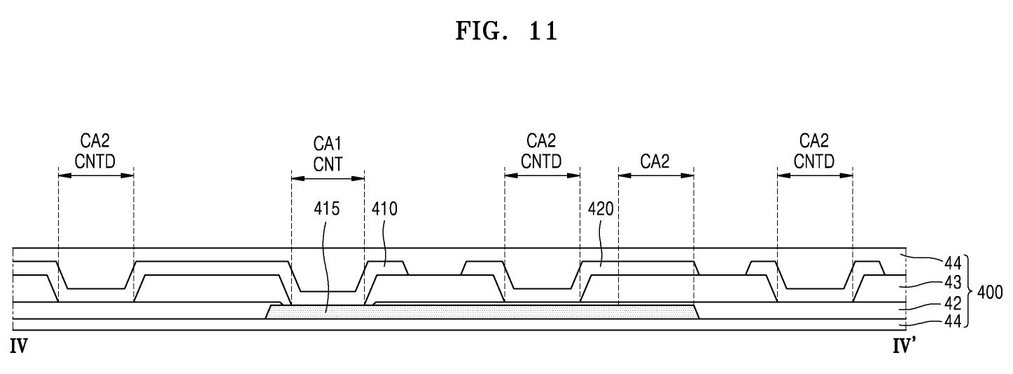

FIG. 10 is a plan view of a touch electrode layer according to an embodiment. FIG. 11 is a cross-sectional view of the touch electrode layer taken along a line IV-IV′ of FIG. 10. In the cross-sectional view of FIG. 11, only the touch electrode layer 400 is illustrated and the other layers are omitted.

Referring to FIGS. 10 and 11, the first touch electrodes 410 (e.g., the first-first touch electrode 411 and the second-first touch electrode 412) and the second touch electrodes 420 (e.g., the first-second touch electrode 421 and the second-second touch electrode 422) may each have a mesh structure in which a plurality of wires intersect with each other in a plan view, and thus the first touch electrodes 410 and the second touch electrodes 420 may each include the intersection area CA that is an area in which wires intersect with each other. As the first-first touch electrode 411 and the second-first touch electrode 412 are electrically connected to each other through the first connection line 415, as described above, the first-first touch electrode 411 and the second-first touch electrode 412 may each include at least one contact portion CNT formed in the intersection area CA1. The dummy contact portion CNTD may be formed in the intersection area CA2 in which the contact portion CNT is not disposed, among the intersection areas CAs included in the first touch electrode 410 and the second touch electrode 420, as illustrated in FIG. 10. In an embodiment, the dummy contact portion CNTD may not be formed in some of the intersection areas CA2. In other words, the dummy contact hole hd may not be formed in some of the intersection area CA2 in which the contact portion CNT is not formed. Accordingly, in the intersection area in which the contact portion CNT or the dummy contact portion CNTD is not formed, the second touch electrode 420 may have a shape that is disposed on the third insulating layer 43, and the second touch electrode 420 may not be in direct contact with the upper surface of the second insulating layer 42.

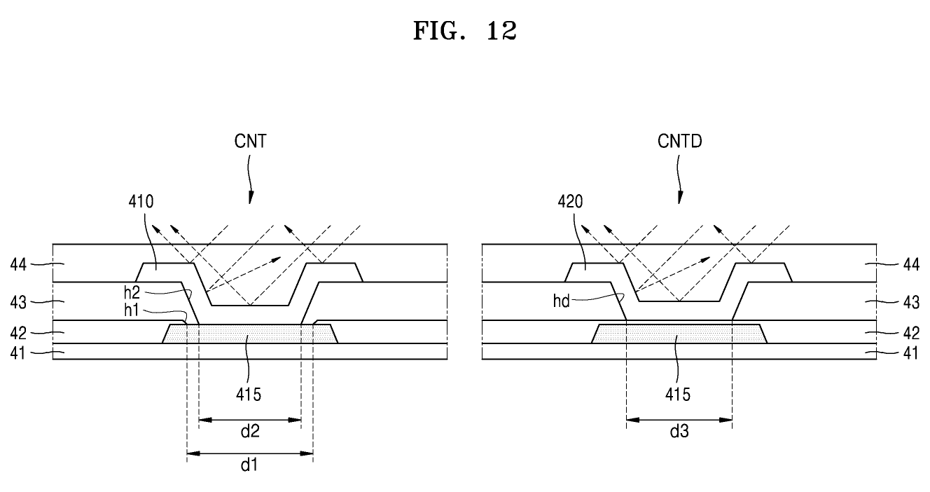

FIG. 12 is a cross-sectional view of the contact portion CNT and the dummy contact portion CNTD, according to an embodiment, and also is a conceptual view showing that external light is incident on a display device including the contact portion CNT and the dummy contact portion CNTD, according to an embodiment.

As described with reference to FIGS. 6-11, in the contact portion CNT, the first contact hole h1 that exposes a part of the upper surface of the first connection line 415 may overlap with the second contact hole h2 that exposes a part of the upper surface of the first connection line 415. At a position corresponding to (e.g., overlapping with) the dummy contact portion CNTD separated from the contact portion CNT, the dummy contact hole hd that exposes a part of the upper surface of the second insulating layer 42 may be formed.

A part of the touch electrode such as, for example, a wire of the touch electrode, may extend to continuously cover a part of an upper surface of the third insulating layer 43, a side surface of the dummy contact hole hd, and the upper surface of the second insulating layer 42 exposed by the dummy contact hole hd.

The part of the wire of the touch electrode may cover the part of the upper surface of the third insulating layer 43, a side surface of the second contact hole h2, and the upper surface of the first connection line 415 exposed by the second contact hole h2. In this state, the width d2 of the second contact hole h2 may be substantially the same as the width d3 of the dummy contact hole hd, and the cross-sectional shape of the touch electrode in the contact portion CNT may be substantially the same as the cross-sectional shape of the touch electrode in the dummy contact portion CNTD. At a position corresponding to (e.g., overlapping with) the contact portion CNT, the width d1 of the first contact hole h1 may be greater than the width d2 of the second contact hole h2.

The dummy contact hole hd and the second contact hole h2 may be formed in the same process as each other, and the widths and the depths of the dummy contact hole hd and the second contact hole h2 may be substantially the same as each other. The side surface of the dummy contact hole hd and the side surface of the second contact hole h2 may each include an inclined surface that is tapered in a forward direction, and the angles of the inclined surfaces may be substantially the same.

The external light incident on the display device 1 may be reflected by the touch electrode. In a comparative example, where there is no dummy contact portion, the external light reflected from a contact portion and the external light reflected from a part of the touch electrode in an area having no contact portion may have different reflection properties so as to be perceived by a user. However, according to the embodiments, as the dummy contact portion CNTD is formed in the intersection area included in the touch electrodes, the cross-sectional shape of the dummy contact portion CNTD of the touch electrode and the cross-sectional shape of the contact portion CNT of the first touch electrode 410 may be made similar to each other, and thus in the dummy contact portion CNTD, the reflection of external light may be induced similarly to the contact portion CNT. Accordingly, in the display device 1, a uniform external light reflection pattern may be formed so that the contact portion CNT may be prevented from being perceived by a user.

Accordingly, the display device including the contact portion CNT and the dummy contact portion CNTD as described above may have excellent screen display quality.

According to an embodiment of the present disclosure, a display device with excellent screen display quality, and an electronic device including the display device, may be implemented. However, scope of the present disclosure is not limited by the above effects.

Embodiments described herein should be considered in a descriptive sense only and not for purposes of limitation. Descriptions of features or aspects within each embodiment of the present disclosure should typically be considered as available for other similar features or aspects in other embodiments of the present disclosure. While one or more embodiments have been described above with reference to the figures, it will be understood by those of ordinary skill in the art that various changes in form and details may be made therein without departing from the spirit and scope of the present disclosure.

What is claimed is:

1. A display device comprising:
a substrate;
a display layer on the substrate and comprising a plurality of pixels;
an encapsulation layer on the display layer;
a first insulating layer on the encapsulation layer;
a second insulating layer on the first insulating layer;
a third insulating layer on the second insulating layer;
a first-first touch electrode on the third insulating layer;
a second-first touch electrode on the third insulating layer, the second-first touch electrode being in a first direction from the first-first touch electrode;
a first-second touch electrode on the third insulating layer;
a second-second touch electrode on the third insulating layer, the second-second touch electrode being in a second direction, intersecting the first direction, from the first-second touch electrode; and
a first connection line between the first insulating layer and the second insulating layer, and connecting the first-first touch electrode and the second-first touch electrode,
wherein the first-first touch electrode is connected to the first connection line through a first-first contact hole of the second insulating layer and a first-second contact hole of the third insulating layer, the first-second contact hole overlapping with the first-first contact hole,
wherein the second-first touch electrode is connected to the first connection line through a second-first contact hole of the second insulating layer and a second-second contact hole of the third insulating layer, the second-second contact hole overlapping with the second-first contact hole, and
wherein at least one from among the first-first touch electrode, the second-first touch electrode, the first-second touch electrode, and the second-second touch electrode comprises a dummy contact portion that is in direct contact with an upper surface of the second insulating layer through a dummy contact hole of the third insulating layer.

2. The display device of claim 1, wherein each of the first-first touch electrode, the second-first touch electrode, the first-second touch electrode, and the second-second touch electrode comprises a mesh structure comprising a plurality of wires, the plurality of wires intersecting with each other in a plan view of the display device.

3. The display device of claim 2, wherein the dummy contact hole overlaps with at least one of intersection areas in which the plurality of wires intersect with each other in the plan view.

4. The display device of claim 2, wherein the first-first contact hole, the first-second contact hole, the second-first contact hole, and the second-second contact hole overlap with at least one of intersection areas in which the plurality of wires intersect with each other in the plan view.

5. The display device of claim 4, wherein the dummy contact hole is in one intersection area from among the intersection areas, the one intersection area not overlapping with the first-first contact hole, the first-second contact hole, the second-first contact hole, and the second-second contact hole.

6. The display device of claim 1, wherein a width of a portion of the first-first contact hole adjacent to an upper surface of the first connection line is greater than a width of a portion of the first-second contact hole adjacent to the upper surface of the first connection line.

7. The display device of claim 1, wherein the second insulating layer comprises an inorganic insulating material, and the third insulating layer comprises an organic insulating material.

8. The display device of claim 1, wherein the dummy contact portion overlaps with the first connection line,
wherein at least one from among the first-first touch electrode, the second-first touch electrode, the first-second touch electrode, and the second-second touch electrode comprises an additional dummy contact portion that is direct contact with the upper surface of the second insulating layer through an additional dummy contact hole of the third insulating layer, and
wherein the additional dummy contact portion does not overlap with the first connection line.

9. The display device of claim 1, wherein each of the first-first touch electrode, the second-first touch electrode, the first-second touch electrode, and the second-second touch electrode comprises a metal.

10. The display device of claim 1, further comprising a second connection line that connects the first-second touch electrode and the second-second touch electrode, and
wherein the second connection line is in a same layer as a layer of the first-second touch electrode and the second-second touch electrode.

11. An electronic device comprising:
a substrate;
a display layer on the substrate and comprising a plurality of pixels;
an encapsulation layer on the display layer;
a first insulating layer on the encapsulation layer;
a second insulating layer on the first insulating layer;
a third insulating layer on the second insulating layer;
a first-first touch electrode on the third insulating layer;
a second-first touch electrode on the third insulating layer, the second-first touch electrode being in a first direction from the first-first touch electrode;
a first-second touch electrode on the third insulating layer;
a second-second touch electrode on the third insulating layer, the second-second touch electrode being in a second direction, intersecting the first direction, from the first-second touch electrode; and
a first connection line between the first insulating layer and the second insulating layer, and connecting the first-first touch electrode and the second-first touch electrode,
wherein each of the first-first touch electrode, the second-first touch electrode, the first-second touch electrode, and the second-second touch electrode comprises a mesh structure comprising a plurality of wires, the plurality of wires intersecting with each other in a plan view,
wherein the first-first touch electrode is connected to the first connection line through a first-first contact hole of the second insulating layer and a first-second contact hole of the third insulating layer, the first-second contact hole overlapping with the first-first contact hole,
wherein the second-first touch electrode is connected to the first connection line through a second-first contact hole of the second insulating layer and a second-second contact hole of the third insulating layer, the second-second contact hole overlapping with the second-first contact hole, and
wherein at least one from among the first-first touch electrode, the second-first touch electrode, the first-second touch electrode, and the second-second touch electrode comprises a dummy contact portion that is in direct contact with an upper surface of the second insulating layer through a dummy contact hole of the third insulating layer.

12. The electronic device of claim 11, wherein the dummy contact hole overlaps with at least one of intersection areas in which the plurality of wires intersect with each other in the plan view.

13. The electronic device of claim 11, wherein the first-first contact hole and the first-second contact hole overlap with at least one of intersection areas in which the plurality of wires intersect with each other in the plan view.

14. The electronic device of claim 13, wherein the dummy contact hole is in one intersection area from among the intersection areas, the one intersection area not overlapping with the first-first contact hole, the second-first contact hole, the second-first contact hole, and the second-second contact hole.

15. The electronic device of claim 11, wherein a width of a portion of the first-first contact hole adjacent to an upper surface of the first connection line is greater than a width of a portion of the first-second contact hole adjacent to the upper surface of the first connection line.

16. The electronic device of claim 11, wherein the second insulating layer comprises an inorganic insulating material, and the third insulating layer comprises an organic insulating material.

17. The electronic device of claim 11, wherein the dummy contact portion overlaps with the first connection line,
wherein at least one from among the first-first touch electrode, the second-first touch electrode, the first-second touch electrode, and the second-second touch electrode comprises an additional dummy contact portion that is in direct contact with the upper surface of the second insulating layer through an additional dummy contact hole of the third insulating layer, and
wherein the additional dummy contact portion does not overlap with the first connection line.

18. The electronic device of claim 11, wherein each of the first-first touch electrode, the second-first touch electrode, the first-second touch electrode, and the second-second touch electrode comprises a metal.

19. The electronic device of claim 11, further comprising a second connection line that connects the first-second touch electrode and the second-second touch electrode, and
wherein the second connection line is in a same layer as a layer of the first-second touch electrode and the second-second touch electrode.

20. A touch electrode layer comprising:
a first insulating layer;
a second insulating layer on the first insulating layer;
a third insulating layer on the second insulating layer;
a first-first touch electrode on the third insulating layer;
a second-first touch electrode on the third insulating layer, the second-first touch electrode being in a first direction from the first-first touch electrode;
a first-second touch electrode on the third insulating layer;
a second-second touch electrode on the third insulating layer, the second-second touch electrode being in a second direction, intersecting the first direction, from the first-second touch electrode; and
a first connection line between the first insulating layer and the second insulating layer, and connecting the first-first touch electrode and the second-first touch electrode,
wherein the first-first touch electrode is connected to the first connection line through a first contact hole of the second insulating layer and a second contact hole of the third insulating layer, the second contact hole overlapping with the first contact hole, and
wherein at least one from among the first-first touch electrode, the second-first touch electrode, the first-second touch electrode, and the second-second touch electrode comprises a dummy contact portion that is in direct contact with an upper surface of the second insulating layer through a dummy contact hole of the third insulating layer.
